(19) United States
(12) Patent Application Publication
(10) Pub. No.: US 2025/0185497 A1
(43) Pub. Date: Jun. 5, 2025

(54) METHOD OF REPAIRING DISPLAY PANEL AND REPAIR DEVICE PERFORMING THE SAME

(71) Applicant: Samsung Display Co., LTD., Yongin-si (KR)

(72) Inventors: Sung Jun KIM, Yongin-si (KR); Seung Noh LEE, Yongin-si (KR)

(21) Appl. No.: 18/891,824

(22) Filed: Sep. 20, 2024

(30) Foreign Application Priority Data
Dec. 5, 2023 (KR) 10-2023-0174694

(51) Int. Cl. H10K 71/00; B23K 26/082

(52) U.S. Cl. CPC H10K 71/861; B23K 26/082

(57) ABSTRACT

A method of repairing a display panel includes inspecting a defect of a first pattern of the display panel, irradiating a first laser having a first pulse width to a defect area where the defect occurs, and irradiating a second laser having a second pulse width different from the first pulse width to the defect area.

### CROSS REFERENCE TO RELATED APPLICATION

The present application claims priority to and the benefit of Korean Patent Application No. 10-2023-0174694, filed on, Dec. 5, 2023, in the Korean Intellectual Property Office, the entire disclosure of which is incorporated by reference herein.

### BACKGROUND

### 1. Field

The present disclosure relates to a method of repairing a display panel and a repair device for performing the same. More specifically, the present disclosure relates to a method of repairing a display panel using a laser and a repair device for performing the same.

### 2. Description of the Related Art

A display device is a device that displays a moving image and/or a still image, and includes a liquid crystal display (LCD), an organic light emitting diode (OLED), and/or the like. The display device is used in various electronic devices such as a mobile phone, a navigation device, a digital camera, an electronic book, a portable game console, and/or various terminals. The display device includes a display panel to provide visual information such as an image or a picture to a user.

It may be determined whether the display panel is defective during manufacturing or after a manufacturing process. At this time, when a defect occurs, the defect of the display panel may be repaired using various methods.

### SUMMARY

Aspects and features of embodiments of the present disclosure are to provide a method of repairing a display panel, which repairs the display panel, by using different lasers. Other aspects and features of embodiments of the present disclosure are to provide a repair device which repairs a display panel.

According to one or more embodiments of the present disclosure, a method of repairing a display panel may include inspecting a defect of a first pattern of the display panel, irradiating a first laser having a first pulse width to a defect area where the defect occurs, and irradiating a second laser having a second pulse width different from the first pulse width to the defect area.

In one or more embodiments, the first pattern may be a multilayer pattern.

In one or more embodiments, the first pattern may include a first layer including aluminum and a second layer on the first layer and including titanium.

In one or more embodiments, the second layer may be removed by the first laser, and the first layer may be removed by the second laser.

In one or more embodiments, the first pattern may further include a third layer located between the first layer and the second layer and including titanium nitride.

In one or more embodiments, the first pattern may include a gate line of the display panel.

In one or more embodiments, the first pattern may be located on the second pattern, and the second pattern may include a channel area of a transistor of the display panel.

In one or more embodiments, the first pulse width may be smaller than the second pulse width.

In one or more embodiments, peak power of the first laser may be greater than peak power of the second laser.

In one or more embodiments, the first laser may be a femtosecond laser.

In one or more embodiments, the second laser may be a nanosecond laser.

In one or more embodiments, the first laser may be irradiated in a scanning method.

In one or more embodiments, the second laser may be irradiated in a stepping method.

According to one or more embodiments of the present disclosure, a repair device repairing a display panel may include a laser irradiator configured to irradiate a first laser having a first pulse width and a second laser having a second pulse width different from the first pulse width to a defect area where a defect of the display panel occurs, and a controller configured to control the laser irradiator.

In one or more embodiments, the repair device may further include a capturing unit configured to capture the display panel to generate image data and provide the image data to the controller, and the controller may be configured to inspect the defect based on the image data.

In one or more embodiments, the first pulse width may be smaller than the second pulse width.

In one or more embodiments, peak power of the first laser may be greater than peak power of the second laser.

In one or more embodiments, the first laser may be a femtosecond laser, and the second laser may be a nanosecond laser.

In one or more embodiments, the laser irradiator may be configured to irradiate the first laser in a scanning method.

In one or more embodiments, the laser irradiator may be configured to irradiate the second laser in a stepping method.

The method of repairing the display panel according to embodiments of the disclosure may effectively repair a multilayer using different lasers

However, an effect, aspects, and features of embodiments of the present disclosure is not limited to the above-described effect, aspects, and features, and may be variously expanded within a range that does not deviate from the spirit and scope of the present disclosure.

### BRIEF DESCRIPTION OF THE DRAWINGS

The above and other aspects and features of embodiments of the present disclosure will become more apparent by describing in further detail embodiments thereof with reference to the accompanying drawings, in which:

FIG. 1 is a schematic perspective view of an electronic device according to one or more embodiments;

FIG. 2 is a perspective view of a display device included in an electronic device according to one or more embodiments;

FIG. 3 is a cross-sectional view of the display device of FIG. 2;

FIG. 4 is a schematic plan view illustrating a connection relationship between components of a display device according to one or more embodiments;

FIG. 5 is a plan view illustrating one or more embodiments of one of the pixels of FIG. 4;

FIG. 6 is a schematic cross-sectional view taken along the line I-I′ of FIG. 5;

FIG. 7 is a plan view illustrating a partial area of a display area of FIG. 4;

FIG. 8 is a plan view illustrating an example in which a defect occurs in a conductive pattern;

FIG. 9 is a cross-sectional view illustrating an example of the conductive pattern of FIG. 8;

FIG. 10 is a flowchart illustrating a method of repairing a display panel according to one or more embodiments of the present disclosure;

FIG. 11 is a block diagram illustrating a repair device performing the method of repairing the display panel of FIG. 10;

FIGS. 12 and 13 are diagrams illustrating the step S200 of FIG. 10; and

FIGS. 14 and 15 are diagrams illustrating the step S300 of FIG. 10.

### DETAILED DESCRIPTION

Hereinafter, embodiments according to the present disclosure are described in detail with reference to the accompanying drawings. It should be noted that in the following description, only portions necessary for understanding an operation according to the present disclosure are described, and descriptions of other portions are omitted in order not to obscure the subject matter of the present disclosure. In addition, the present disclosure may be embodied in other forms without being limited to embodiments described herein. However, embodiments described herein are provided to describe the present disclosure in sufficient detail for those skilled in the art to which the present disclosure pertains to implement the technical spirit and scope of the present disclosure.

Throughout the present disclosure, in a case where a portion is “connected” to another portion, the case includes not only a case where the portion is “directly connected” but also a case where the portion is “indirectly connected” with another element interposed therebetween. Terms used herein are for describing specific embodiments and are not intended to limit the present disclosure. Throughout the present disclosure, in a case where a certain portion “includes”, the case means that the portion may further include another component without excluding another component unless otherwise stated. “At least one of X, Y, and Z”, “at least one of X, Y, or Z”, and “at least one selected from a group consisting of X, Y, and Z” may be interpreted as one X, one Y, one Z, or any combination of two or more of X, Y, and Z (for example, XYZ, XYY, YZ, and ZZ). Here, “and/or” includes all combinations of one or more of corresponding configurations.

Here, terms such as first and second may be used to describe various components, but these components are not limited to these terms. These terms are used to distinguish one component from another component. Therefore, a first component may refer to a second component within a range without departing from the spirit and scope of the present disclosure.

Spatially relative terms such as “under”, “on”, and the like may be used for descriptive purposes, thereby describing a relationship between one element or feature and another element(s) or feature(s) as shown in the drawings. Spatially relative terms are intended to include other directions in use, in operation, and/or in manufacturing, in addition to the direction depicted in the drawings. For example, when a device shown in the drawing is turned upside down, elements depicted as being positioned “under” other elements or features are positioned in a direction “on” the other elements or features. Therefore, in one or more embodiments, the term “under” may include both directions of on and under. In addition, the device may face in other directions (for example, rotated 90 degrees or in other directions) and thus the spatially relative terms used herein are interpreted according thereto.

Various embodiments are described with reference to drawings schematically illustrating ideal embodiments. Accordingly, it will be expected that shapes may vary, for example, according to tolerances and/or manufacturing techniques. Therefore, embodiments disclosed herein cannot be construed as being limited to shown specific shapes, and should be interpreted as including, for example, changes in shapes that occur as a result of manufacturing. As described above, the shapes shown in the drawings may not show actual shapes of areas of a device, and the present disclosure is not limited thereto.

Hereinafter, the present disclosure is described in more detail with reference to the attached drawings.

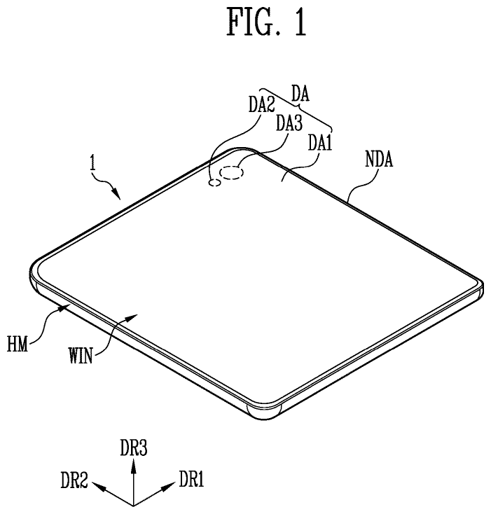

FIG. 1 is a schematic perspective view of an electronic device according to one or more embodiments.

Referring to FIG. 1, the electronic device 1 may be an electronic device that provides a display screen capable of displaying a moving image and/or a still image in a third direction DR3, and for example, a television, a notebook computer, a monitor, a billboard, Internet of things, a mobile phone, a smart phone, a tablet personal computer (PC), an electronic watch, a smart watch, a watch phone, a head-mounted display, a mobile communication terminal, an electronic notebook, an electronic book, a portable multimedia player (PMP), a navigation device, a game console, a digital camera, a camcorder, and/or the like providing a display screen may be included in the electronic device 1.

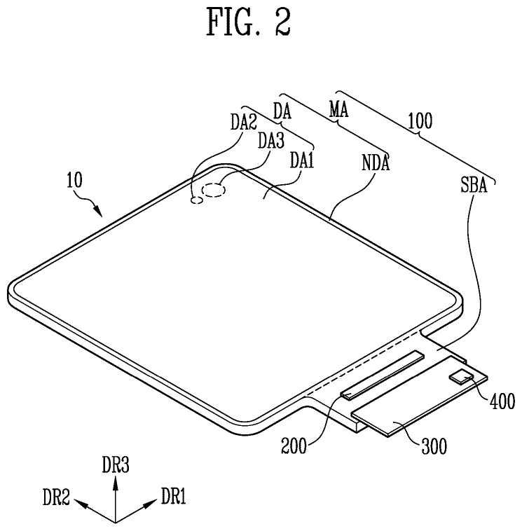

The electronic device 1 may include a cover window WIN and a housing HM, and a display device 10 shown in FIG. 2 may be positioned inside the cover window WIN and the housing HM. Therefore, the cover window WIN and the housing HM may be combined to configure an exterior of the electronic device 1.

The cover window WIN may include an insulating panel. For example, the cover window WIN may be formed of glass, plastic, or a combination thereof. In one or more embodiments, the cover window WIN may include a touch sensor capable of sensing a touch.

A front surface of the cover window WIN may define a front surface of the electronic device 1.

The housing HM may be combined with the cover window WIN. The cover window WIN may be disposed on a front surface of the housing HM. The housing HM may be combined with the cover window WIN to provide a desired receiving space (e.g., a predetermined receiving space). The display device 10 may be received in a desired receiving space (e.g., a predetermined receiving space) provided between the housing HM and the cover window WIN.

The housing HM may include a material with relatively high rigidity. For example, the housing HM may include a plurality of frames and/or plates including glass, plastic, and/or metal, or formed of a combination thereof. The housing HM may have a rear surface and a side surface, the cover window WIN may be disposed on the housing HM, configurations of the display device 10 received in an internal space formed by the housing HM and the cover window WIN may be stably protected from external shock.

The electronic device 1 may include the display device (refer to 10 of FIG. 2) that provides the display screen in the third direction DR3. As the display device included in the electronic device 1, various display devices such as an inorganic light emitting element display device, an organic light emitting display device, and/or a quantum dot light emitting display device may be provided. Hereinafter, the present disclosure is described based on a case to which a light emitting display device including an organic light emitting element (OLED) is applied as an example of the display device, but the present disclosure is not limited thereto, and the same technical idea may be applied to another display device when the same technical idea is applicable.

A shape of the electronic device 1 may be variously modified. For example, the electronic device 1 may have a shape such as a rectangle of which a horizontal length is long, a rectangle of which a vertical length is long, a square, a quadrangle of which a corner portion (e.g., a corner) is rounded, other polygon, and/or a circle. A shape of a display area DA of the electronic device 1 may also be similar to an overall shape of the electronic device 1. In FIG. 1, the electronic device 1 of a rectangular shape of which a length of a first direction is relatively long is shown, but the present disclosure is not limited thereto.

The electronic device 1 may include the display area DA and a non-display area NDA around the display area DA along an edge or a periphery of the display area DA. The display area DA and the non-display area NDA shown in FIG. 1 may correspond to the display area DA and the non-display area NDA of the display device 10. The display area DA is an area where an image is displayed, and the non-display area NDA is an area where no image is displayed. The display area DA generally may occupy most of an area based on a center of the electronic device 1, and the non-display area NDA may have a structure surrounding the periphery of the display area DA.

The display area DA may include a first display area DA1, a second display area DA2, and a third display area DA3. The second display area DA2 and the third display area DA3 may be an area where a component such as a sensor and/or a camera for adding various functions to the electronic device 1 is disposed on a rear surface (e.g., a surface positioned in a lower surface of the third direction DR3), and the second display area DA2 and the third display area DA3 may correspond to a component area. The second display area DA2 and the third display area DA3 may be surrounded by the first display area DA1. For example, the first display area DA1 may be around the second display area DA2 and the third display area DA3. In addition to the first display area DA1, both of the second display area DA2 and the third display area DA3 may display an image. A position and the number of the second display area DA2 and the third display area DA3 may be variously changed according to one or more embodiments.

Hereinafter, a structure of the display device, which is an example of the display device, is described through FIG. 2.

FIG. 2 is a perspective view of a display device included in an electronic device according to one or more embodiments.

Referring to FIG. 2, the electronic device 1 according to one or more embodiments may include the display device 10. The display device 10 may display an image in the electronic device 1 and may sense and/or capture a front surface of the electronic device 1. The display device 10 may have a planar shape similar to that of the electronic device 1. For example, the display device 10 may have a shape similar to a quadrangle having a side extending in a first direction DR1 and a side extending in a second direction DR2. A corner where the side extending in the first direction DR1 and the side extending in the second direction DR2 meet may be formed roundly to have a curvature, but is not limited thereto and may also be formed at a right angle. The planar shape of the display device 10 is not limited to a quadrangle, and may be formed similarly to another polygon, circle, and/or ellipse.

The display device 10 may include a display panel 100, a display driver 200, a circuit board 300, and a touch driver 400.

The display panel 100 may include a main area MA and a sub-area SBA.

The main area MA may include the display area DA including pixels displaying an image, and the non-display area NDA disposed around the display area DA along the edge or the periphery of the display area DA. The display area DA may include the first display area DA1, the second display area DA2, and the third display area DA3. The second display area DA2 and the third display area DA3 may include the pixels, a component such as a sensor and/or a camera may be disposed in a lower portion of the third direction DR3, and the second display area DA2 and the third display area DA3 may correspond to a component area.

The display area DA may emit light in the third direction DR3 from a plurality of emission areas corresponding to a plurality of light emitting elements. For example, the display panel 100 may include a pixel circuit unit including a transistor, and a pixel defining layer including a light emitting element and having an opening defining the emission area of the light emitting element. Here, the light emitting element may include at least one of an organic light emitting element (e.g., an organic light emitting diode (OLED)) including an organic light emitting layer, a quantum dot light emitting element (e.g., a quantum dot LED) including a quantum dot light emitting layer, an inorganic light emitting element (e.g., an inorganic LED) including an inorganic semiconductor, and a micro light emitting element (e.g., a micro LED), but is not limited thereto.

The non-display area NDA is an area outside the display area DA and surrounds the display area DA. The non-display area NDA may be defined as an edge area of the main area MA of the display panel 100. The non-display area NDA may include a gate driver that supplies gate signals to the gate lines, and fan out lines connecting a display driver 200 and the display area DA.

The sub-area SBA may be an area extending from one side of the main area MA. The sub-area SBA may include a flexible material capable of bending, folding, rolling, and/or the like. For example, when the sub-area SBA is bent, the sub-area SBA may overlap the main area MA in a thickness direction (e.g., the third direction DR3). The sub-area SBA may include the display driver 200 and a pad unit connected to the circuit board 300. In one or more embodiments, the sub-area SBA may be omitted, and the display driver 200 and the pad unit may be disposed in the non-display area NDA.

The display driver 200 may output signals and voltages for driving the display panel 100. The display driver 200 may supply data voltages to data lines. The display driver 200 may supply a power voltage to a power line and may supply a gate control signal to the gate driver. The display driver 200 may be formed of an integrated circuit (IC) and may be mounted on the display panel 100 in a chip on glass (COG) method, a chip on plastic (COP) method, and/or an ultrasonic bonding method. For example, the display driver 200 may be disposed in the sub-area SBA and may overlap the main area MA in the thickness direction (e.g., the third direction DR3) by bending of the sub-area SBA. As another example, the display driver 200 may be mounted on the circuit board 300.

The circuit board 300 may be attached to the pad unit of the display panel 100 using an anisotropic conductive film (ACF). Lead lines of the circuit board 300 may be electrically connected to the pad unit of the display panel 100. The circuit board 300 may be a flexible printed circuit board (FPCB), a printed circuit board (PCB), or a flexible film such as a chip on film (COF).

The touch driver 400 may be mounted on the circuit board 300. The touch driver 400 may be electrically connected to a touch sensor included in the electronic device 1. The touch driver 400 may supply a touch driving signal to a plurality of sensing electrodes of the touch sensor and sense a change amount of a capacitance between the plurality of sensing electrodes. For example, the touch driving signal may be a pulse signal having a desired frequency (e.g., a predetermined frequency). The touch driver 400 may determine whether a touch is input and calculate a touch input coordinate based on the change amount of the capacitance between the plurality of sensing electrodes. Touch driver 400 may be formed as an integrated circuit (IC).

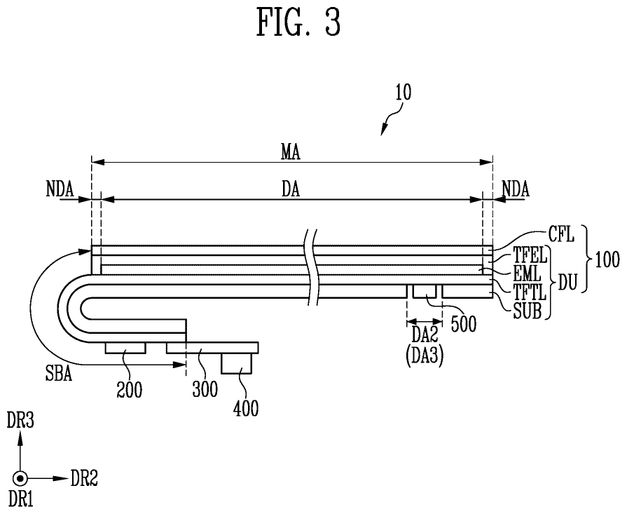

Hereinafter, a cross-sectional structure of the display device 10 is described through FIG. 3.

FIG. 3 is a cross-sectional view of the display device of FIG. 2.

Referring to FIG. 3, the display panel 100 may include a display layer DU and an external light reduction layer CFL. The display layer DU may include a substrate SUB, a driving element layer TFTL, a light emitting element layer EML, and an encapsulation layer TFEL.

The substrate SUB may be a base substrate or a base member. The substrate SUB may be a flexible substrate capable of bending, folding, rolling, and/or the like. For example, the substrate SUB may include a polymer resin such as polyimide (PI), but is not limited thereto. In one or more embodiments, the substrate SUB may include a glass material and/or a metal material.

The driving element layer TFTL may be disposed on the substrate SUB. The driving element layer TFTL may include a plurality of transistors and a capacitor configuring a pixel circuit unit that outputs and transmits a current to the light emitting element. The driving element layer TFTL may further include gate lines, data lines, power lines, gate control lines, fan out lines connecting the display driver 200 and the data lines, and lead lines connecting the display driver 200 and the pad unit. Each transistor may include a semiconductor including a channel area, a source area, and a drain area, and a gate electrode positioned on one side of the semiconductor. Here, the source area and the drain area of the semiconductor may serve as a source electrode (e.g., a first electrode) and a drain electrode (e.g., a second electrode) of the transistor, respectively. In addition, when the gate driver is formed on one side of the non-display area NDA of the display panel 100, the gate driver may include transistors.

The driving element layer TFTL may be disposed in the display area DA, the non-display area NDA, and the sub-area SBA. The transistors, the gate lines, the data lines, and the power lines of the driving element layer TFTL may be disposed in the display area DA. The gate control lines and the fan out lines of the driving element layer TFTL may be disposed in the non-display area NDA. The lead lines of the driving element layer TFTL may be disposed in the sub-area SBA.

In the light emitting element layer EML, a light emitting element and an emission area corresponding thereto may be positioned, and the light emitting element layer EML may be disposed on the driving element layer TFTL. The light emitting element layer EML may include a plurality of light emitting elements including a first electrode, a second electrode, and a light emitting layer that emit light, and a pixel defining layer having an opening (hereinafter also referred to as a pixel opening) defining the emission area. The plurality of light emitting elements of the light emitting element layer EML may be disposed in the display area DA.

In one or more embodiments, the light emitting layer may be an organic light emitting layer including an organic material. A functional layer including at least one of an electron injection layer, an electron transport layer, a hole transport layer, and a hole injection layer may be positioned on both sides of the light emitting layer. Here, an addition of the light emitting layer and the functional layer may be referred to as an intermediate layer. When the first electrode receives a voltage through the transistor of the driving element layer TFTL and the second electrode receives a driving low voltage, a hole and an electron may be moved through the hole transport layer, and the electron transport layer, respectively, and the hole and the electron may combine with each other in the organic light emitting layer to emit light. Here, one of the first electrode and the second electrode may be an anode, and the other may be a cathode.

In one or more embodiments, the light emitting element may be a quantum dot light emitting element including a quantum dot light emitting layer, an inorganic light emitting element including an inorganic semiconductor, or a micro light emitting element.

The encapsulation layer TFEL may cover an upper surface and a side surface of the light emitting element layer EML and may protect external moisture and air from entering the light emitting element layer EML. The encapsulation layer TFEL may include at least one inorganic layer and at least one organic layer for encapsulating the light emitting element layer EML.

The external light reduction layer CFL may be disposed on the encapsulation layer TFEL. The external light reduction layer CFL may include a plurality of color filters corresponding to a plurality of respective emission areas. In addition, a light blocking member may overlap and may be positioned between color filters adjacent to the external light reduction layer CFL or in an overlap portion where adjacent color filters overlap. The light blocking member may be positioned on or under the color filter in the third direction DR3, or may be positioned on both sides based on the color filter.

Because the external light reduction layer CFL is directly disposed on the encapsulation layer TFEL, the display device 10 may not require a separate substrate for the external light reduction layer CFL. In addition, a polarizing plate is not attached on the external light reduction layer CFL. As a result, a thickness of the display device 10 may be relatively small. In addition, because the display device 10 does not include a polarizing plate, although direct reflection of external light may occur, the reflection of external light may be reduced by the color filter and/or the light blocking member included in the external light reduction layer CFL. That is, because the color filters selectively transmit light of a specific wavelength and block and/or absorb light of another wavelength, and the light blocking member absorbs external light, light amount of external light flowing into the display device 10 may be reduced, an amount of reflected light may also be reduced, and thus the reflection of external light may be reduced.

According to one or more embodiments, the display device 10 may further include an optical device 500. The optical device 500 may be disposed on a rear surface of the second display area DA2 or the third display area DA3. The optical device 500 may emit and/or receive light of infrared, ultraviolet, and visible light bands. For example, the optical device 500 may be an optical sensor that senses light incident on the display device 10, such as a proximity sensor, an illumination sensor, and/or a camera sensor and/or an image sensor.

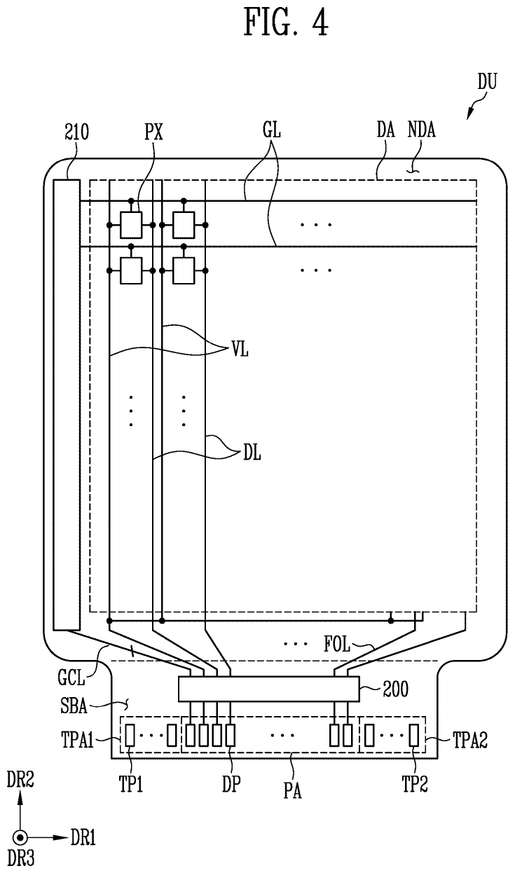

Hereinafter, a connection relationships of a component included in the display device 10 is specifically described through FIG. 4.

FIG. 4 is a schematic plan view illustrating a connection relationship between a component of a display device according to one or more embodiments.

Referring to FIG. 4, the display layer DU of the display device 10 may include the display area DA and the non-display area NDA.

The display area DA may be disposed at a center of the display panel 100. A plurality of unit pixels PX, a plurality of gate lines GL, a plurality of data lines DL, and a plurality of power lines VL may be disposed in the display area DA. Each of the plurality of unit pixels PX may be a minimum unit that emits light and includes a pixel circuit unit including a transistor and a capacitor and a light emitting element that receives a current from the pixel circuit unit.

Each unit pixel PX may be connected to the gate line GL, the data line DL, and the power line VL, and each of the gate line GL and the power line VL may include a plurality of lines.

The plurality of gate lines GL may supply a gate signal received from the gate driver 210 to the plurality of unit pixels PX. The plurality of gate lines GL may extend in the first direction DR1 and may be spaced from each other in the second direction DR2 crossing the first direction DR1.

The plurality of data lines DL may supply a data voltage received from the display driver 200 to the plurality of unit pixels PX. The plurality of data lines DL may extend in the second direction DR2 and may be spaced from each other in the first direction DR1.

The plurality of power lines VL may supply a power voltage received from the display driver 200 to the plurality of unit pixels PX. Here, the power voltage may be at least one of a driving voltage, an initialization voltage, a reference voltage, and/or a driving low voltage, and a plurality of these power voltages may be transmitted to the unit pixel PX. The plurality of power lines VL may extend in the second direction DR2 and may be spaced from each other in the first direction DR1.

The non-display area NDA may surround the display area DA. A gate driver 210, fan out lines FOL, and gate control lines GCL may be disposed in the non-display area NDA.

The gate driver 210 may generate a plurality of gate signals based on the gate control signal and sequentially supply the plurality of gate signals to the plurality of gate lines GL in a set order.

The fan out lines FOL may extend from the display driver 200 to the display area DA. The fan out lines FOL may supply the data voltage received from the display driver 200 to the plurality of data lines DL.

The gate control line GCL may extend from the display driver 200 to the gate driver 210. The gate control line GCL may supply the gate control signal received from the display driver 200 to the gate driver 210.

Referring to FIG. 4, the display device 10 may further include the sub-area SBA.

The sub-area SBA may include the display driver 200, a pad area PA, and first and second touch pad areas TPA1 and TPA2.

The display driver 200 may output signals and voltages for driving the display panel 100 to the fan out lines FOL. The display driver 200 may supply the data voltage to the data line DL through the fan out lines FOL. The data voltage may be supplied to a plurality of unit pixels PX, and a luminance of the plurality of unit pixels PX may be controlled. The display driver 200 may supply the gate control signal to the gate driver 210 through the gate control line GCL.

The pad area PA, the first touch pad area TPA1, and the second touch pad area TPA2 may be disposed at an edge of the sub-area SBA. The pad area PA may include a plurality of display pad units DP. The plurality of display pad units DP may be connected to a graphic system through the circuit board 300. The plurality of display pad units DP may be connected to the circuit board 300 to receive digital video data and supply the digital video data to the display driver 200. Each of the first touch pad area TPA1 and the second touch pad area TPA2 may include a plurality of touch pads TP1 and TP2, and may be connected to the touch driver 400 positioned on the circuit board 300 to enable the display device to sense a touch. The pad area PA, the first touch pad area TPA1, and the second touch pad area TPA2 may be electrically connected to the circuit board 300 using an anisotropic conductive film and/or a material such as self-assembly anisotropic conductive paste (SAP).

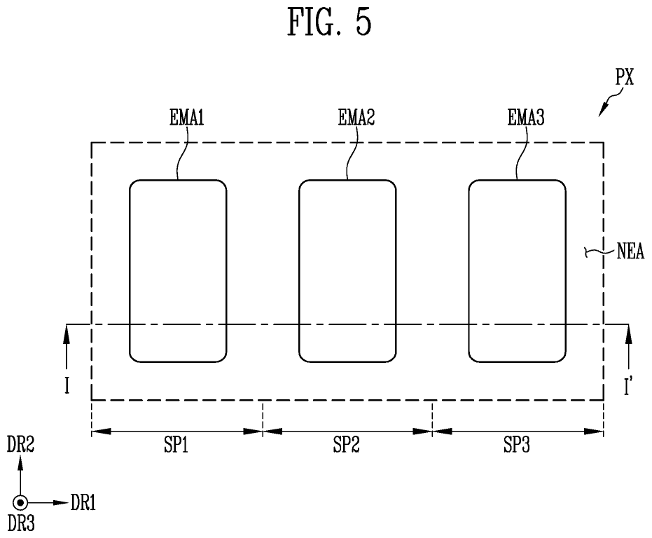

FIG. 5 is a plan view illustrating one or more embodiments of one of the pixels of FIG. 4.

Referring to FIGS. 4 and 5, the pixel PX may include first to third sub-pixels SP1 to SP3 arranged along the first direction DR1.

The first sub-pixel SP1 may include a first emission area EMA1 and a non-emission area NEA around the first emission area EMA1. The second sub-pixel SP2 may include a second emission area EMA2 and a non-emission area NEA around the second emission area EMA2. The third sub-pixel SP3 may include a third emission area EMA3 and a non-emission area NEA around the third emission area EMA3.

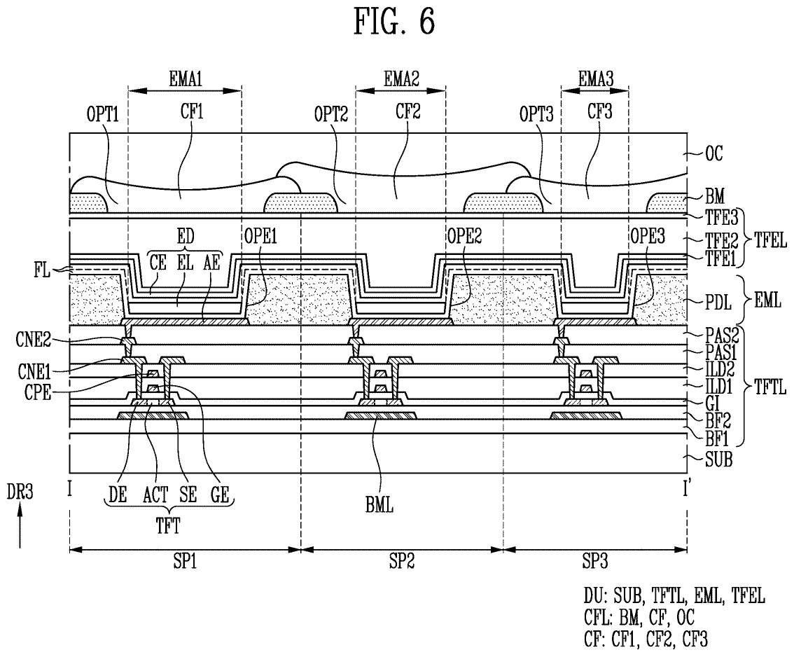

The first emission area EMA1 may be an area where light is emitted from a portion of the light emitting element layer EML (refer to FIG. 6) corresponding to the first sub-pixel SP1. The second emission area EMA2 may be an area where light is emitted from a portion of the light emitting element layer EML corresponding to the second sub-pixel SP2. The third emission area EMA3 may be an area where light is emitted from a portion of the light emitting element layer EML corresponding to the third sub-pixel SP3. The respective emission areas EMA1 to EMA3 may be understood as an opening of the pixel defining layer PDL corresponding to the respective first to third sub-pixels SP1 to SP3.

However, a disposition or an arrangement of the sub-pixels SP1 to SP3 is not limited to that shown in FIG. 5.

FIG. 6 is a schematic cross-sectional view taken along the line I-I′ of FIG. 5.

FIG. 6 shows a cross-section crossing the first emission area EMA1, the second emission area EMA2, and the third emission area EMA3.

The display panel 100 of the display device 10 may include the display layer DU and the external light reduction layer CFL. The display layer DU may include the substrate SUB, the driving element layer TFTL, the light emitting element layer EML, and the encapsulation layer TFEL. In the display panel 100, the external light reduction layer CFL disposed on an encapsulation layer TFEL may include a light blocking member BM and color filters CF1, CF2, and CF3, and the color filters CF1, CF2, and CF3 may be positioned on the light blocking member BM. Here, the light blocking member BM overlaps an overlap portion of the color filters CF1, CF2, and CF3.

The substrate SUB may be a base substrate or a base member. The substrate SUB may be a flexible substrate capable of bending, folding, rolling, and/or the like. For example, the substrate SUB may include a polymer resin such as polyimide (PI), but is not limited thereto. As another example, the substrate SUB may include a glass material and/or a metal material.

The driving element layer TFTL may include a first buffer layer BF1, a lower metal layer BML, a second buffer layer BF2, a transistor TFT, a gate insulating layer GI, a first interlayer insulating layer ILD1, a capacitor electrode CPE, a second interlayer insulating layer ILD2, a first connection electrode CNE1, a first protective layer PAS1, a second connection electrode CNE2, and a second protective layer PAS2.

The first buffer layer BF1 may be disposed on the substrate SUB. The first buffer layer BF1 may include an inorganic layer that may prevent permeation of air or moisture. For example, the first buffer layer BF1 may include a plurality of inorganic layers alternately stacked. According to one or more embodiments, the first buffer layer BF1 may be omitted.

The lower metal layer BML may be disposed on the first buffer layer BF1. For example, the lower metal layer BML may be formed as a single layer or multiple layers formed of one of molybdenum (Mo), aluminum (Al), chromium (Cr), gold (Au), titanium (Ti), nickel (Ni), neodymium (Nd), and/or copper (Cu), and/or an alloy thereof.

The second buffer layer BF2 may cover the first buffer layer BF1 and the lower metal layer BML. The second buffer layer BF2 may include an inorganic layer that may prevent permeation of air or moisture. For example, the second buffer layer BF2 may include a plurality of inorganic layers alternately stacked.

The transistor TFT may be disposed on the second buffer layer BF2, and the transistor TFT may be a driving transistor or a switching transistor of the pixel circuit unit. The transistor TFT may include a semiconductor layer ACT, a source electrode SE, a drain electrode DE, and a gate electrode GE.

The semiconductor layer ACT may be disposed on the second buffer layer BF2. The semiconductor layer ACT may overlap the lower metal layer BML and the gate electrode GE in the thickness direction of the substrate SUB (e.g., the third direction DR3), and may be insulated from the gate electrode GE by the gate insulating layer GI. In a portion of the semiconductor layer ACT, a material of the semiconductor layer ACT may be conductive, and thus the source electrode SE and the drain electrode DE may be formed. The semiconductor layer ACT may be positioned between the source electrode SE and the drain electrode DE, and may include an undoped channel layer.

The gate electrode GE may be disposed on the gate insulating layer GI. The gate electrode GE may overlap the semiconductor layer ACT with the gate insulating layer GI interposed therebetween.

The gate insulating layer GI may be disposed on the semiconductor layer ACT and the second buffer layer BF2. For example, the gate insulating layer GI may cover the semiconductor layer ACT and the second buffer layer BF2, and may insulate the semiconductor layer ACT and the gate electrode GE. The gate insulating layer GI may include a contact hole through which the first connection electrode CNE1 passes.

The first interlayer insulating layer ILD1 may cover the gate electrode GE and the gate insulating layer GI. The first interlayer insulating layer ILD1 may include a contact hole through which the first connection electrode CNE1 passes. The contact hole of the first interlayer insulating layer ILD1 may be connected to the contact hole of the gate insulating layer GI and a contact hole of the second interlayer insulating layer ILD2.

The capacitor electrode CPE may be disposed on the first interlayer insulating layer ILD1. The capacitor electrode CPE may overlap the gate electrode GE in the thickness direction of the substrate SUB (e.g., in the third direction DR3). The capacitor electrode CPE and the gate electrode GE may form a capacitance.

The second interlayer insulating layer ILD2 may cover the capacitor electrode CPE and the first interlayer insulating layer ILD1. The second interlayer insulating layer ILD2 may include the contact hole through which the first connection electrode CNE1 passes. The contact hole of the second interlayer insulating layer ILD2 may be connected to the contact hole of the first interlayer insulating layer ILD1 and the contact hole of the gate insulating layer GI.

The first connection electrode CNE1 may be disposed on the second interlayer insulating layer ILD2. The first connection electrode CNE1 may electrically connect the drain electrode DE of the transistor TFT and the second connection electrode CNE2. The first connection electrode CNE1 may be inserted into the contact hole formed in the second interlayer insulating layer ILD2, the first interlayer insulating layer ILD1, and the gate insulating layer GI to be in contact with the drain electrode DE of the transistor TFT.

The first protective layer PAS1 may cover the first connection electrode CNE1 and the second interlayer insulating layer ILD2. The first protective layer PAS1 may protect the transistor TFT. The first protective layer PAS1 may include a contact hole through which the second connection electrode CNE2 passes.

The second connection electrode CNE2 may be disposed on the first protective layer PAS1. The second connection electrode CNE2 may electrically connect the first connection electrode CNE1 and a pixel electrode AE (hereinafter also referred to as an anode or a first electrode) of a light emitting element ED. The second connection electrode CNE2 may be inserted into the contact hole formed in the first protective layer PAS1 to be in contact with the first connection electrode CNE1.

The second protective layer PAS2 may cover the second connection electrode CNE2 and the first protective layer PAS1. The second protective layer PAS2 may include a contact hole through which the pixel electrode AE of the light emitting element ED passes.

The light emitting element layer EML may be disposed on the driving element layer TFTL. The light emitting element layer EML may include the light emitting element ED and the pixel defining layer PDL. The light emitting element ED may include the pixel electrode AE, a light emitting layer EL, and a common electrode CE (hereinafter also referred to as a second electrode or a cathode). The light emitting element ED may additionally include at least one layer from among a hole injection layer, a hole transport layer, an electron injection layer, and an electron transport layer, and may further include a functional layer FL positioned on both sides of the light emitting layer EL.

The pixel electrode AE may be disposed on the second protective layer PAS2. The pixel electrode AE may be disposed to overlap one of pixel openings OPE1, OPE2, and OPE3 of the pixel defining layer PDL. The pixel electrode AE may be electrically connected to the drain electrode DE of the transistor TFT through the first and second connection electrodes CNE1 and CNE2.

The light emitting layer EL may be disposed on the pixel electrode AE. For example, the light emitting layer EL may be an organic light emitting layer formed of an organic material, but is not limited thereto. The functional layer FL may be positioned on both sides of the light emitting layer EL, the functional layer FL positioned between the light emitting layer EL and the pixel electrode AE may include the hole injection layer and/or the hole transport layer, and the functional layer FL positioned between the light emitting layer EL and the common electrode CE may include the electron transport layer and/or the electron injection layer. In a case where the light emitting layer EL corresponds to the organic light emitting layer, when the transistor TFT applies a predetermined voltage to the pixel electrode AE of the light emitting element ED and the common electrode CE of the light emitting element ED receives a common voltage or the driving low voltage, holes and electrons may be moved to the light emitting layer EL through the hole transport layer and the electron transport layer, respectively, a current may flow through the light emitting element ED, and the holes and the electrons may combine with each other in the light emitting layer EL to emit light.

The common electrode CE may be disposed on the light emitting layer EL. For example, the common electrode CE may be implemented in an electrode form common to all pixels rather than being differentiated for each of a plurality of pixels. The common electrode CE may be disposed on the light emitting layer EL in the first to third emission areas EMA1, EMA2, and EMA3, and may be disposed on the pixel defining layer PDL in an area excluding the first to third emission areas EMA1, EMA2, and EMA3. The functional layer FL may be positioned between the pixel defining layer PDL and the common electrode CE.

The common electrode CE may receive the common voltage or the driving low voltage. When the pixel electrode AE receives a voltage corresponding to the data voltage and the common electrode CE receives the driving low voltage, a potential difference is formed between the pixel electrode AE and the common electrode CE, a current flows, and thus the light emitting layer EL emits light.

The pixel defining layer PDL may be disposed on a portion of the pixel electrode AE and the second protective layer PAS2. The pixel defining layer PDL may expose a portion of the pixel electrode AE. As described above, the pixel defining layer PDL may define the first to third emission areas EMA1 to EMA3, and areas or sizes thereof may be different from each other. The pixel defining layer PDL may space and insulate the pixel electrodes AE of each of a plurality of light emitting elements ED. The pixel defining layer PDL may be a black pixel defining layer that includes a light absorbing material to prevent reflection of external light. For example, the pixel defining layer PDL may include a polyimide (PI)-based binder and a pigment in which red, green, and/or blue are mixed. Alternatively, the pixel defining layer PDL may include a mixture of cardo-based binder resin, lactam-based black pigment, and/or a blue pigment. Alternatively, the pixel defining layer PDL may include carbon black.

FIG. 6 shows the pixel defining layer PDL in a trapezoidal shape for convenience of description, and is not limited to a shape of the pixel defining layer PDL.

The encapsulation layer TFEL may be disposed on the common electrode CE to cover a plurality of light emitting elements ED. The encapsulation layer TFEL may include at least one inorganic layer and may prevent oxygen and/or moisture from permeating into the light emitting element layer EML. The encapsulation layer TFEL may include at least one organic layer and may protect the light emitting element layer EML from a foreign substance such as dust.

The encapsulation layer TFEL in FIG. 6 may include a first encapsulation layer TFE1, a second encapsulation layer TFE2, and a third encapsulation layer TFE3. The first encapsulation layer TFE1 and the third encapsulation layer TFE3 may be inorganic encapsulation layers, and the second encapsulation layer TFE2 disposed between the first encapsulation layer TFE1 and the third encapsulation layer TFE3 may be an organic encapsulation layer.

Each of the first encapsulation layer TFE1 and the third encapsulation layer TFE3 may include one or more inorganic insulating materials. The inorganic insulating material may include aluminum oxide, titanium oxide, tantalum oxide, hafnium oxide, zinc oxide, silicon oxide, silicon nitride, and/or silicon oxynitride.

The second encapsulation layer TFE2 may include a polymer-based material. The polymer-based material may include acryl-based resin, epoxy-based resin, polyimide, polyethylene, and/or the like. For example, the second encapsulation layer TFE2 may include an acryl-based resin, such as polymethyl methacrylate and/or polyacrylic acid. The second encapsulation layer TFE2 may be formed by curing a monomer and/or applying a polymer.

The external light reduction layer CFL positioned on the encapsulation layer TFEL includes the light blocking member BM and the color filters CF1, CF2, and CF3. The color filters CF1, CF2, and CF3 may be positioned on the light blocking member BM. Here, the light blocking member BM overlaps the overlap portion of the color filters CF1, CF2, and CF3.

The light blocking member BM may be disposed on the encapsulation layer TFEL. The light blocking member BM may include a light absorbing material. For example, the light blocking member BM may include an inorganic black pigment and/or an organic black pigment. The inorganic black pigment may be carbon black, and the organic black pigment may include at least one of lactam black, perylene black, and/or aniline black, and the present disclosure is not limited thereto. The light blocking member BM may improve a color reproduction rate of the display device 10 by preventing visible light from invading and mixing colors between the first to third emission areas EMA1, EMA2, and EMA3.

The color filters CF1, CF2, and CF3 of the external light reduction layer CFL may be disposed on the light blocking member BM. The different color filters CF1, CF2, and CF3 may be disposed to correspond to the different emission areas EMA1, EMA2, and EMA3 or the pixel openings OPE1, OPE2, and OPE3 of the pixel defining layer PDL, and light blocking openings OPT1, OPT2, and OPT3 of the light blocking member BM, respectively. For example, the first color filter CF1 may be disposed to correspond to the first emission area EMA1, the second color filter CF2 may be disposed to correspond to the second emission area EMA2, and the third color filter CF3 may be disposed to correspond to the third emission area EMA3.

The external light reduction layer CFL may further include a planarization layer OC, and the planarization layer OC may be disposed on the color filters CF1, CF2, and CF3 to planarize an upper end of the color filters CF1, CF2, and CF3. The planarization layer OC may be a colorless light-transmissive layer that does not have a color in a visible light band. For example, the planarization layer OC may include a colorless, light-transmissive organic material such as an acryl-based resin.

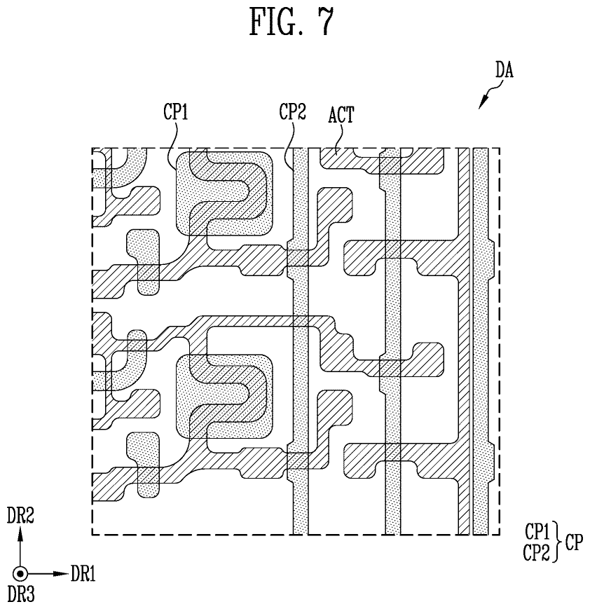

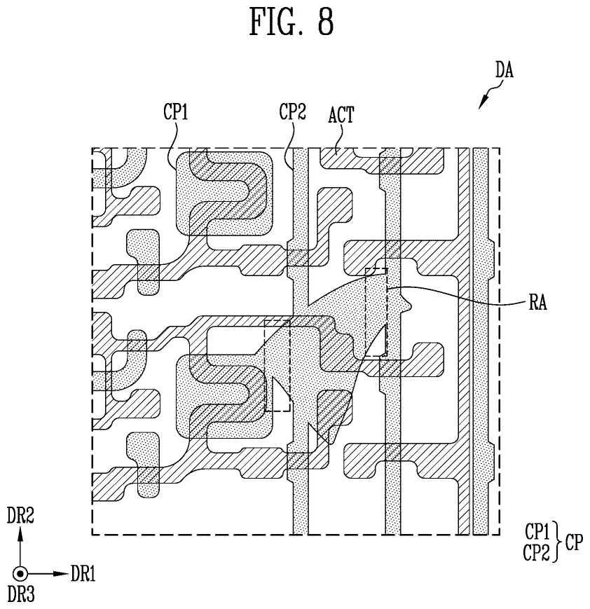

FIG. 7 is a plan view illustrating a partial area of the display area of FIG. 4, and FIG. 8 is a plan view illustrating an example in which a defect occurs in a conductive pattern.

FIGS. 7 and 8 illustrates only a conductive pattern CP forming the gate electrode GE (refer to FIG. 6) or the gate line GL (refer to FIG. 4), and an active pattern forming the semiconductor layer ACT (refer to FIG. 6) for convenience of description.

Referring to FIGS. 4, 6, and 7, the conductive pattern CP forming the gate electrode GE or the gate line GL may be disposed in the display area DA. The active pattern forming the channel area (or a channel layer) of the transistor TFT may be disposed in the display area DA. For example, a first conductive pattern CP1 may form the gate electrode GE and may form the transistor together with the active pattern. For example, a second conductive pattern CP2 may form the gate line GL.

Referring to FIG. 8, a defect may occur in a process of forming the conductive pattern CP. For example, as shown in FIG. 8, a defect such as contact of the first conductive pattern CP1 and the second conductive pattern CP2, or contact between the second conductive patterns CP2 forming different gate lines GL (refer to FIG. 4) may occur.

When the defect is discovered during a manufacturing process of the display panel, a process of repairing a defect area RA where the defect occurred is required to remove the defect. For example, the process of repairing may be a process of removing the defect area RA.

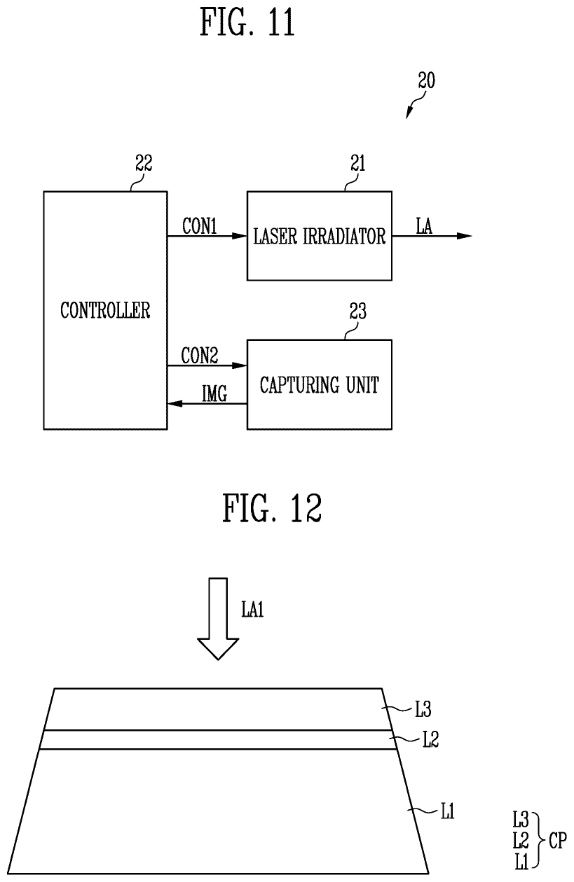

The defect area RA refers to an area repaired by a repair device 20 (refer to FIG. 11) to be described later. In the present embodiment, the defect area RA is illustrated in a quadrangular shape, but the present disclosure is not limited to a shape of the defect area RA.

The defect according to the present disclosure only refers to a defect that is required to be removed, and the shape of the defect is not limited.

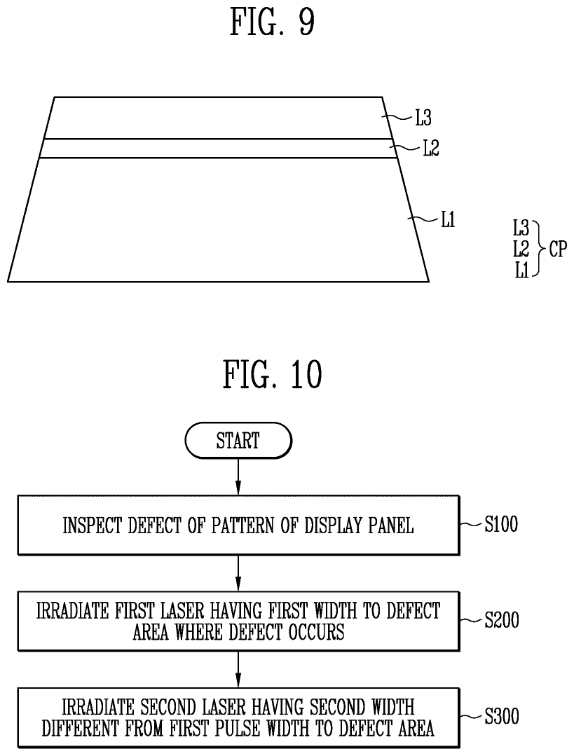

Hereinafter, the repair process is specifically described with reference to FIGS. 9-15.

FIG. 9 is a cross-sectional view illustrating an example of the conductive pattern of FIG. 8.

Referring to FIG. 9, the conductive pattern CP may be formed as a multilayer pattern. In order to reduce a resistance of the gate line GL, the conductive pattern CP is required to be formed of a material with a low resistance (for example, aluminum (Al)). However, in a case of a material that is vulnerable to cleaning through heat and chemicals, such as aluminum (Al), using the material as the conductive pattern CP alone may be difficult. Therefore, the conductive pattern CP may be formed as a multilayer pattern including different materials.

For example, the conductive pattern CP may include a first layer L1 including aluminum (Al), a second layer L2 including titanium nitride (TiN), and a third layer L3 including titanium (Ti).

However, the present disclosure is not limited to a type and the number of materials forming the multilayer conductive pattern CP.

FIG. 10 is a flowchart illustrating a method of repairing a display panel according to one or more embodiments of the present disclosure.

Referring to FIG. 10, the method of repairing the display panel may include inspecting a defect of a pattern of a display panel (S100), irradiating a first laser having a first pulse width to a defect area where the defect occurs (S200), and irradiating a second laser having a second pulse width different from the first pulse width to the defect area (S300).

Hereinafter, the present disclosure is specifically described with reference to FIGS. 11-15.

FIG. 11 is a block diagram illustrating the repair device that performs the method of repairing the display panel of FIG. 10.

Referring to FIG. 11, the repair device may include a laser irradiator 21, a controller 22, and a capturing unit 23.

The laser irradiator 21 may receive a first control signal CON1 from the controller 22 and irradiate laser LA. The first control signal CON1 may include a pulse width, an irradiation time, an irradiation position, an irradiation method, and/or the like of the laser LA.

The capturing unit 23 may capture an image on the display panel 100 (refer to FIG. 2) to generate image data IMG, and provide the image data IMG to the controller 22. The capturing unit 23 may capture the display panel 100 (refer to FIG. 2) by receiving a second control signal CON2 from the controller 22. The second control signal CON2 may include a capturing position, a capturing angle, and/or the like.

The controller 22 may inspect the defect of the display panel 100 (refer to FIG. 2) based on the image data IMG. In addition, when the defect occurs, the controller 22 may control the laser irradiator 21 so that the laser irradiator 21 removes the defect area RA (refer to FIG. 8) where the defect occurs.

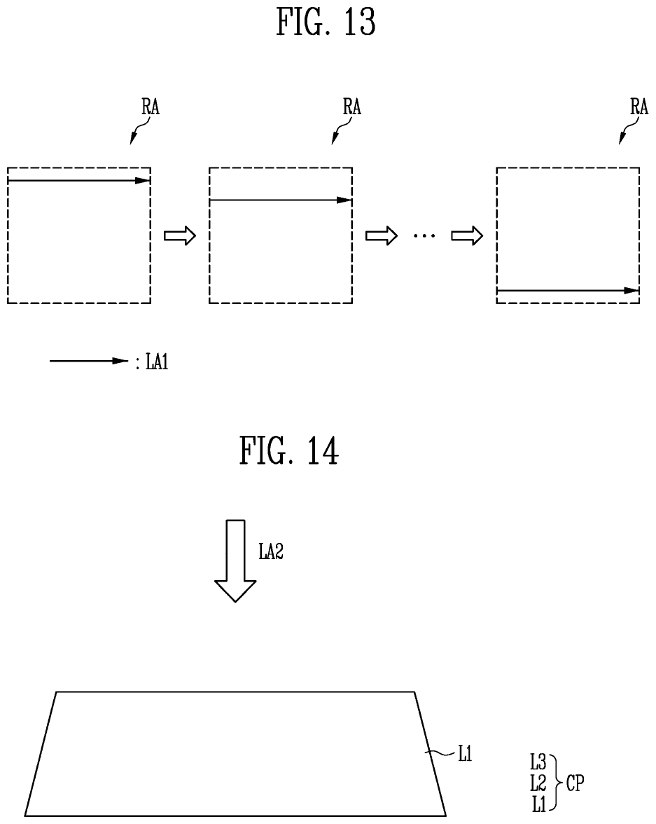

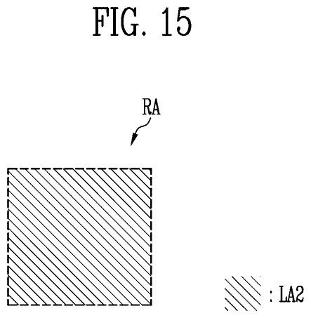

FIGS. 12 and 13 are diagrams illustrating the step S200 of FIG. 10, and FIGS. 14 and 15 are diagrams illustrating the step S300 of FIG. 10.

Referring to FIGS. 8 and 12-14, the second layer L2 and the third layer L3 of the conductive pattern CP of the defect area RA may be removed by the first laser LA1, and the first layer L1 of the conductive pattern CP of the defect area RA may be removed by the second laser LA2.

As described above, the conductive pattern CP may be formed as a multilayer pattern. For example, the first layer L1 may include aluminum (Al), the second layer L2 may include titanium nitride (TiN), and the third layer L3 may include titanium (Ti).

The first pulse width of the first laser LA1 may be narrower than the second pulse width of the second laser LA2, and peak power of the first laser LA1 may be greater than peak power of the second laser LA2. For example, the first laser LA1 may be an ultra-fast laser. For example, the first laser LA1 may be a picosecond laser, a femtosecond laser, and/or an attosecond laser. For example, the second laser LA2 may be a nanosecond laser.

Referring to FIG. 12, a laser with a relatively narrow pulse width may be used as the first laser LA1. When a pulse width of the first laser LA1 is wide, heat may be gradually generated and diffused after irradiation, and the first layer L1 may melt and shrink due to the heat. Therefore, an ultra-fast laser with a relatively narrow pulse width may be used as the first laser LA1.

Referring to FIG. 13, peak power of the first laser LA1 may be higher than that of the second laser LA2. Therefore, when the first laser LA1 is irradiated in a stepping method, a lower layer (for example, the active pattern) may be damaged. Therefore, the first laser LA1 may be irradiated in a scanning method.

As shown in FIG. 13, the scanning method is a method of sequentially irradiating a laser in a unit of a certain area (for example, one line in FIG. 13) in the defect area RA. As shown in FIG. 15, the stepping method is a method of concurrently (e.g., simultaneously) irradiating a laser to the entire defect area RA. However, the present disclosure is not limited to a shape of the certain area described above.

Referring to FIG. 14, a laser with a relatively wide pulse width may be used as the second laser LA2. When the pulse width of the first laser LA1 is narrow, a large number of remaining particles may be generated due to the high peak power, and the lower layer (for example, the active pattern) may be damaged. Therefore, a nanosecond laser may be used as the second laser LA2.

Referring to FIG. 15, the peak power of the second laser LA2 may be lower than that of the first laser LA1. Therefore, when the second laser LA2 is irradiated in the scanning method, the defect area RA may not be completely removed because energy is weak. Therefore, the second laser LA2 may be irradiated in the stepping method.

However, the present disclosure is not limited to an order of irradiating the laser. For example, the order of irradiating the laser may vary according to a material of a pattern.

In addition, the present disclosure is not limited to the method of irradiating the laser (for example, the stepping method, the scanning method, and/or the like). For example, the method of irradiating the laser may vary according to the material of the pattern.

Although specific embodiments and application examples are described herein, these are provided only to facilitate a more general understanding of the present disclosure, the present disclosure is not limited to the above-described embodiments, and those of ordinary skill in the field to which the present disclosure pertains may variously correct and modify from such a description.

Therefore, the spirit and scope of the present disclosure should not be limited to the described embodiments, and the claims described below and all modifications that are equal or equivalent to the claim may fall within the scope of the spirit of the present disclosure.

The present disclosure may be applied to a display device and an electronic device including the display device. For example, the present disclosure may be applied to a digital TV, a 3D TV, a mobile phone, a smart phone, a tablet computer, a VR device, a PC, a home electronic device, a notebook computer, a PDA, a PMP, a digital camera, a music player, a portable game console, a navigation system, and/or the like.

Although described with reference to the above embodiments, it will be understood that those skilled in the art can variously modify and change the present disclosure without departing from the spirit and scope of the present disclosure described in the claims below.

What is claimed is:

1. A method of repairing a display panel, the method comprising:
inspecting a defect of a first pattern of the display panel;
irradiating a first laser having a first pulse width to a defect area where the defect occurs; and
irradiating a second laser having a second pulse width different from the first pulse width to the defect area.

2. The method according to claim 1, wherein the first pattern is a multilayer pattern.

3. The display panel of claim 2, wherein the first pattern comprises a first layer comprising aluminum and a second layer on the first layer and comprising titanium.

4. The method according to claim 3, wherein the second layer is removed by the first laser, and
wherein the first layer is removed by the second laser.

5. The method according to claim 3, wherein the first pattern further comprises a third layer located between the first layer and the second layer and comprising titanium nitride.

6. The method according to claim 1, wherein the first pattern comprises a gate line of the display panel.

7. The method according to claim 6, wherein the first pattern is located on the second pattern, and
wherein the second pattern comprises a channel area of a transistor of the display panel.

8. The method according to claim 1, wherein the first pulse width is smaller than the second pulse width.

9. The method according to claim 1, wherein peak power of the first laser is greater than peak power of the second laser.

10. The method according to claim 1, wherein the first laser is a femtosecond laser.

11. The method according to claim 1, wherein the second laser is a nanosecond laser.

12. The method according to claim 1, wherein the first laser is irradiated in a scanning method.

13. The method according to claim 1, wherein the second laser is irradiated in a stepping method.

14. A repair device repairing a display panel, comprising:
a laser irradiator configured to irradiate a first laser having a first pulse width and a second laser having a second pulse width different from the first pulse width to a defect area where a defect of the display panel occurs; and
a controller configured to control the laser irradiator.

15. The repair device according to claim 14, further comprising:
a capturing unit configured to capture the display panel to generate image data and provide the image data to the controller,
wherein the controller is configured to inspect the defect based on the image data.

16. The repair device according to claim 14, wherein the first pulse width is smaller than the second pulse width.

17. The repair device according to claim 14, wherein peak power of the first laser is greater than peak power of the second laser.

18. The repair device according to claim 14, wherein the first laser is a femtosecond laser, and
wherein the second laser is a nanosecond laser.

19. The repair device according to claim 14, wherein the laser irradiator is configured to irradiate the first laser in a scanning method.

20. The repair device according to claim 14, wherein the laser irradiator is configured to irradiate the second laser in a stepping method.
